(19) United States
(12) Patent Application Publication
(10) Pub. No.: US 2011/0042777 A1
(43) Pub. Date: Feb. 24, 2011

(54) Deep trench isolation structure

(76) Inventors: You-Di Jhang, Taipei Hsien (TW); Chun-Yao Huang, Hsinchu City (TW); Kuo-Hua Ho, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 12/542,721

(22) Filed: Aug. 18, 2009

(51) Int. Cl. H01L 29/06

(52) U.S. Cl. 257/506; 257/E29.02

(57) ABSTRACT

A deep trench isolation structure including a deep trench disposed within a substrate to surround an active area on the substrate and a dielectric material filled within the deep trench. The deep trench comprises at least a corner in an arc shape layout or in a polygonal line shape layout. Accordingly, the deep trench isolation structure can be obtained in a better stress condition and with less process time for trench filling.

### BACKGROUND OF THE INVENTION

1. Field of the Invention

The present invention relates to an isolation structure, and particularly a deep trench isolation structure for semiconductor devices.

2. Description of the Prior Art

In SHV (Super High Voltage) devices, deep trench isolation (DTI) structures are generally utilized for device isolation. Deposition and etching of silicon trenches are important manufacturing steps for void-less filling of deep trenches. The deep trench is formed by etching in a semiconductor substrate and dielectric material is filled into the deep trench by, for example, LPCVD (low pressure chemical vapor deposition) using TEOS (tetraethyl orthosilicate) as raw material.

The conventional deep trench isolation has a right-angled corner layout, as shown in FIG. 1. The deep trench 2 has four right corners 4. During the filling of dielectric material into the trench in the manufacturing process of the deep trench isolation, a gap at the trench corner is found when strait part of the deep trench has already been filled up. It needs extra run time to fill the gap at the corner. FIG. 2 is a scanning electron microscopic (SEM) photograph illustrating the situation of a gap existing among the dielectric material filled within the corner.

Therefore, it is needed for a novel deep trench isolation structure to avoid formation of gap during manufacturing processes.

### SUMMARY OF THE INVENTION

An objective of the present invention is to provide a deep trench isolation structure to solve the aforesaid problem.

In one aspect, the deep trench isolation structure according to the present invention comprises a deep trench disposed within a substrate to surround an active area on the substrate, wherein the deep trench comprises at least a corner in an arc shape layout; and a dielectric material filled within the deep trench.

In another aspect, the deep trench isolation structure according to the present invention comprises a deep trench disposed within a substrate to surround an active area on the substrate, wherein the deep trench comprises at least a corner in a polygonal line shape layout; and a dielectric material filled within the deep trench.

In the present invention, the corner layout of the deep trench isolation is in an arc (or referred to as “curve”) shape or in a polygonal line shape, instead of the conventional right-angle shape, and, accordingly, the deep trench isolation structure can be obtained under a better stress condition and with less process time for trench filling.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view of a conventional deep trench isolation structure;

FIG. 2 is an electron microscopic photograph illustrating the situation of a gap existing among the filled dielectric material at the corner during a manufacturing process for a conventional deep trench isolation structure;

FIG. 3 is a schematic top view of an embodiment of a deep trench isolation structure according to the present invention;

FIG. 4 illustrates a schematic diagram of a corner layout of a deep trench isolation structure of one embodiment according to the present invention;

FIG. 5 illustrates a schematic diagram of a corner layout of a deep trench isolation structure of another embodiment according to the present invention;

FIG. 6 is an electron microscopic photograph of a corner of a deep trench isolation structure of one embodiment according to the present invention;

FIG. 7 is an electron microscopic photograph of a corner of a deep trench isolation structure of another embodiment according to the present invention; and

FIGS. 8 and 9 are electron microscopic photographs showing the results of the experiments with various deep trench isolation structures according to the present invention.

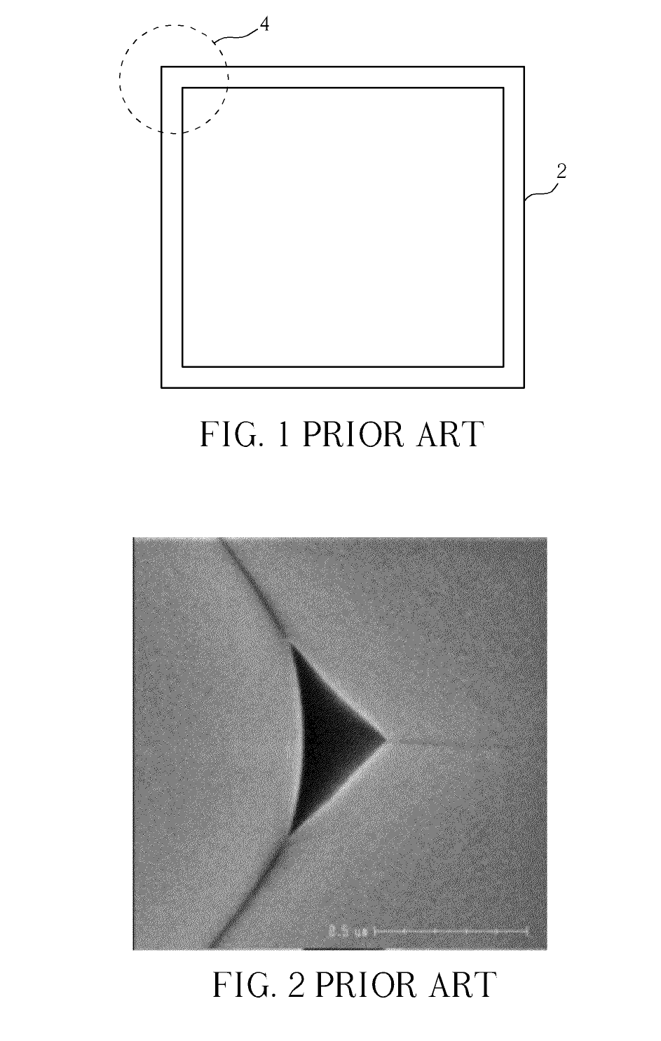

### DETAILED DESCRIPTION

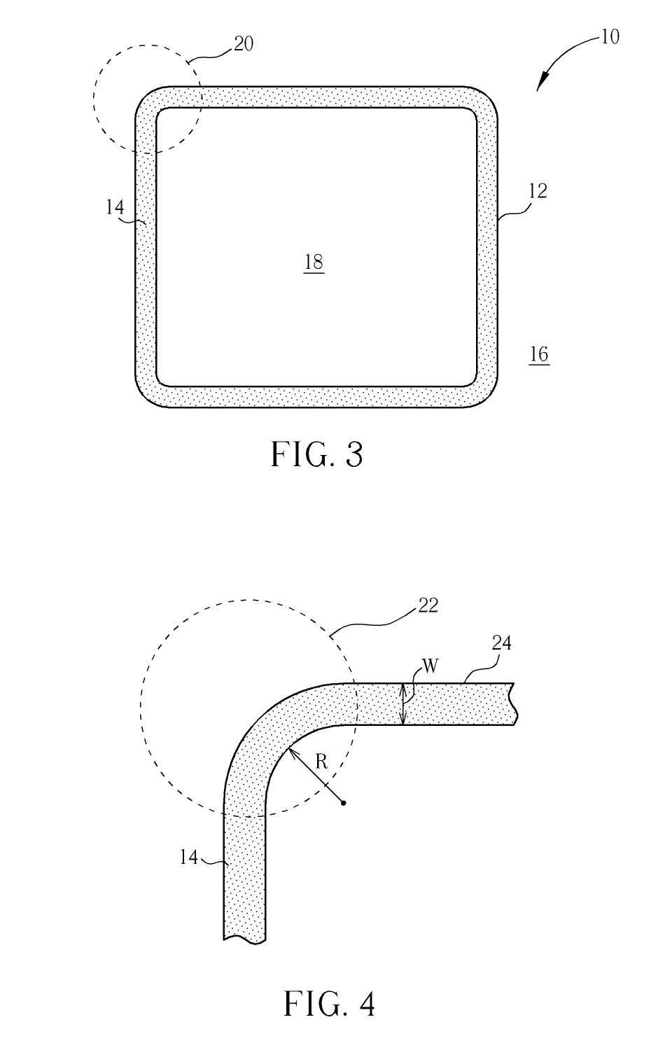

FIG. 3 is a schematic top view for illustrating an embodiment of a deep trench isolation structure according to the present invention. The deep trench isolation structure 10 comprises a deep trench 12 and a dielectric material 14 filled within the deep trench 12. The dielectric material 14 may include for example oxide material or other insulation material. The deep trench 12 is disposed within a substrate 16 and surrounds an active area 18 on the substrate 16. The substrate 16 may be a semiconductor substrate. The deep trench 12 comprises at least a corner 20 as indicated by the circle in the drawing. Herein, the “corner” means the turning place of the deep trench in top view and deemed as a wide line with a width of the deep trench per se. The deep trench 12 may be in a depth of, for example, 1 μm to 30 μm, and with a width of, for example, 0.5 μm to 5 μm, but it is not particularly limited thereto, as long as the deep trench isolation structure can function well as an electrical isolation structure as desired in the device. The layout of the whole deep trench 12 is not limited to a particular shape; however, it is characterized that the deep trench comprises at least a corner and the corner may be in an arc shape layout or in a polygonal line shape layout. The embodiment shown in FIG. 3 has four corners each in an arc shape layout.

The deep trench isolation structure may be in a closed shape layout or not. For one embodiment, the deep trench isolation structure may be in a closed shape layout composed of four corners and four sides. The adjacent two sides are supposed to be perpendicular to each other, but, in fact, they meet each other to become as a corner in an arc shape layout or in a polygonal line shape layout, instead of perpendicular intersection. Furthermore, the distance from each of the corners to the geometric center of the deep trench isolation structure may be greater than the distance from each of the sides to the geometric center of the deep trench isolation structure.

FIG. 4 illustrates a schematic diagram of a corner layout of a deep trench isolation structure of one embodiment according to the present invention. The corner 22 is in an arc shape layout. Since the deep trench has a width truly, the arc shape has an outer curve and an inner curve. In case the deep trench 24 has a trench width W of less than 4.5 μm, it is preferably that the inner curve may have a radius of curvature (R) more than 1 μm. When the radius of curvature of the inner curve is too small, a chink is easily formed during the trench filling.

In case the corner is in a polygonal line shape layout, it may include a plurality of bending locations exhibiting as angles, and preferably the angles are obtuse angles, and more preferably all the angles are protrude angles. Preferably, the polygonal line shape layout has a minimal width equal to d₁ and a maximal width equal to d₂, and (d₂−d₁)/d₁ is less than (√2−1)/1. The convex polygonal line shape may be approximately an arc shape.

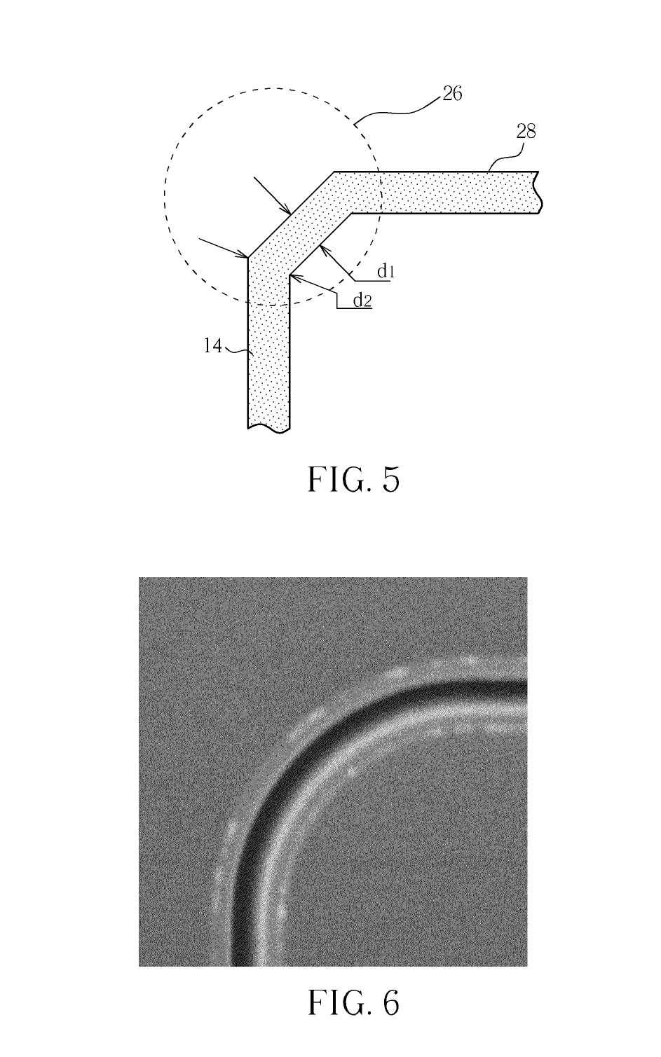

FIG. 5 illustrates a schematic diagram of a corner layout of a deep trench isolation structure of another embodiment according to the present invention. The corner 26 of the deep trench 28 is in a polygonal line shape layout having two bends or angles. FIG. 5 further shows the minimum of the width of the deep trench 28 is indicated by d₁ and the maximum of the width of the deep trench 28 is indicated by d₂. (d₂−d₁)/d₁<(√2−1)/1.

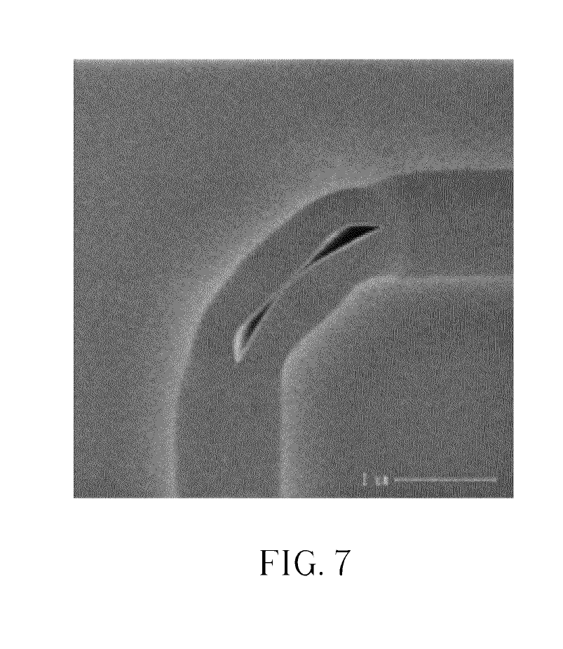

FIG. 6 and FIG. 7 are electron microscopic photographs of an arc-shaped corner and a polygonal-line-shaped corner of two deep trench isolation structures of two embodiments according to the present invention, respectively. FIG. 6 shows a well-filled trench corner, and FIG. 7 shows an almost well-filled trench corner, yet better than conventional one with a right-angled shape. To fill up the trench as shown in FIG. 7, it needs a little more time but won't be longer than that needed for a conventional deep trench filling process.

The deep trench isolation according to the present invention may be formed through forming a patterned mask on a semiconductor substrate to expose the area to be etched, dry etching the area to be etched to form a deep trench having at least a corner in an arc shape layout or in a polygonal line shape layout, and filling the trench with for example silicon oxide by for example LPCVD process using for example TEOS as raw material (hereinafter, the process is referred to as “LPTEOS”). Under conditions of the LPCVD process for example as the same to the conventional technique, the trench filling for the present invention needs less process time for the trench having the particular shape. Furthermore, due to the arc or approximate arc shape in which the corner is formed, the deep trench isolation structure is in a better stress condition.

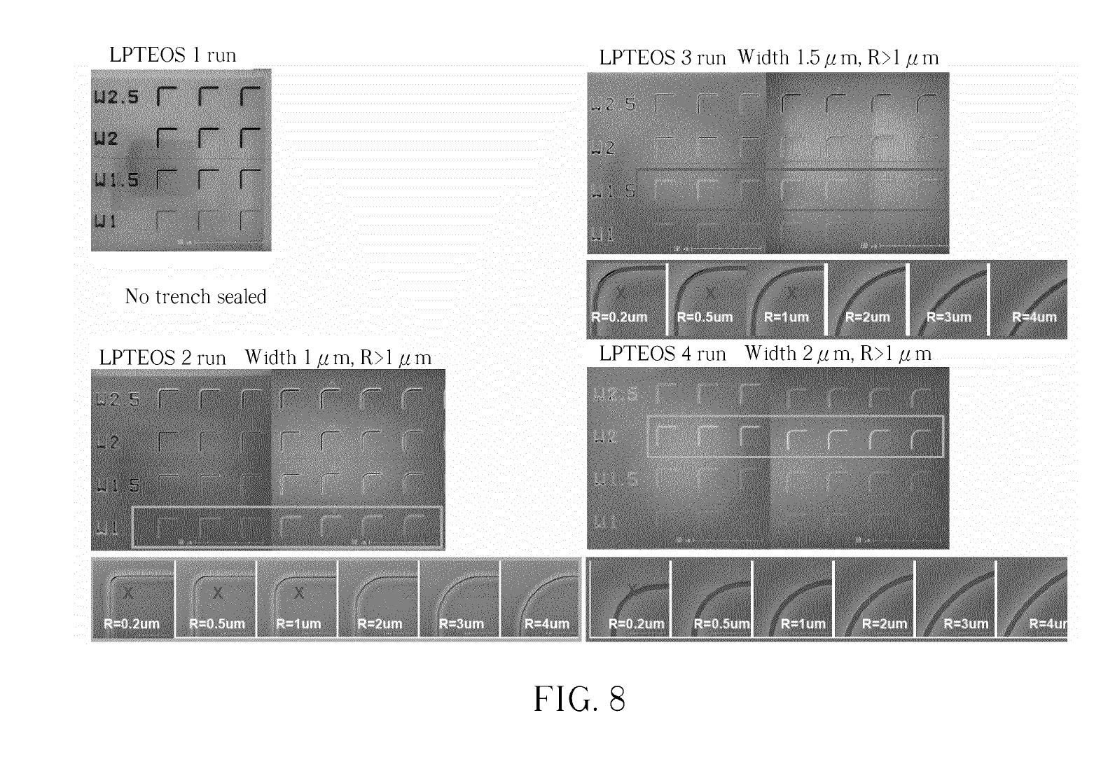

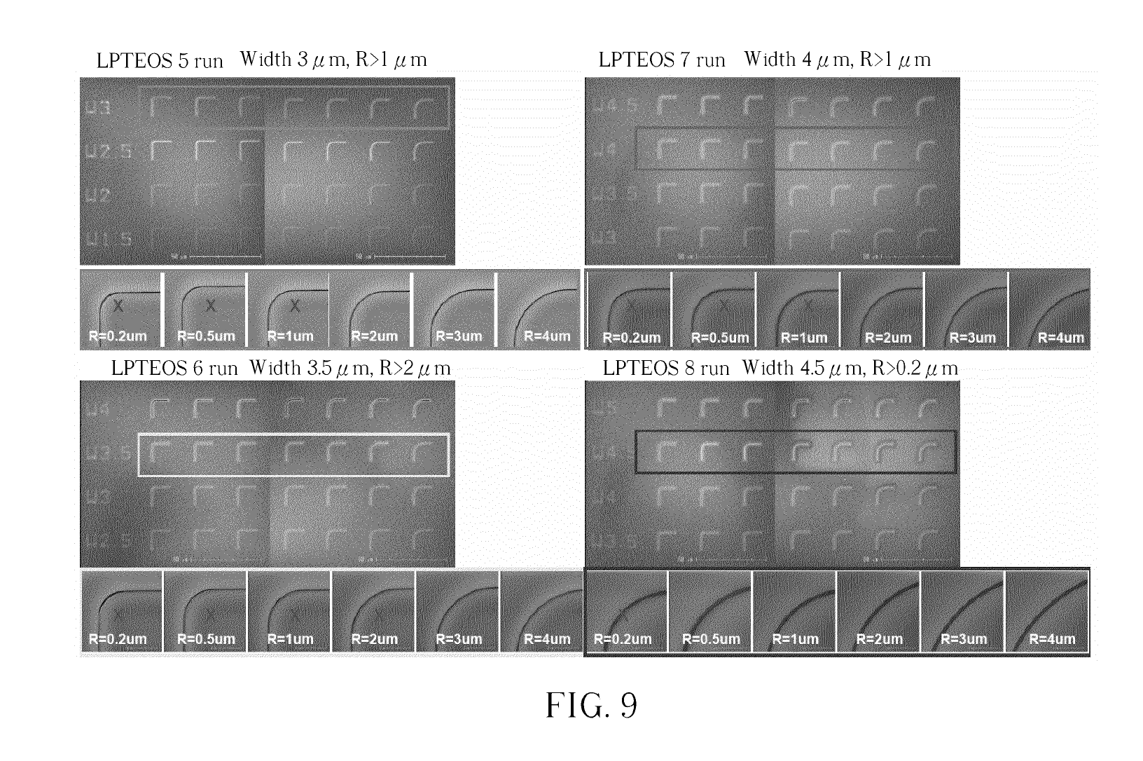

Trench filling by LPCVD SiO₂ or Poly-Si (or referred to as polysilicon) was performed on various deep trenches with widths of 4.5, 4, 3.5, 3, 2.5, 2, 1.5, and 1 μm respectively with right angle and curvature layouts having radii of curvature (R) of 0.2, 0.5, 1, 2, 3, and 4 μm respectively according to the present invention and the results are shown in FIGS. 8 and 9 and described as follows. When the strait part of trench was filled up, the corners were evaluated. For run 1, no trenches are filled up (or sealed). For run 2, the trenches with width of 1 μm with R of 2, 3, and 4 μm were sealed. For run 3, the trenches with width of 1.5 μm with R of 2, 3, and 4 μm were sealed. For run 4, the trenches with width of 2 μm with R of 0.5, 1, 2, 3, and 4 μm were sealed. For run 5, the trenches with width of 3 μm with R of 2, 3, and 4 μm were sealed. For run 6, the trenches with width of 3.5 μm with R of 3 and 4 μm were sealed. For run 7, the trenches with widths of 4 μm with R of 2, 3, and 4 μm were sealed. For run 8, the trenches with widths of 4.5 μm with R of 0.5, 1, 2, 3, and 4 μm were sealed. The process condition can be further optimized with respect to the quality of the trench and manufacturing throughput.

All combinations and sub-combinations of the above-described features also belong to the present invention. Those skilled in the art will readily observe that numerous modifications and alterations of the device and method may be made while retaining the teachings of the invention.

What is claimed is:

1. A deep trench isolation structure, comprising:
a deep trench disposed within a substrate to surround an active area on the substrate, wherein the deep trench comprises at least a corner in an arc shape layout; and
a dielectric material filled within the deep trench.

2. The deep trench isolation structure of claim 1, wherein the deep trench has a trench width of less than 4.5 μm, and thereby the arc shape has an outer curve and an inner curve, wherein the inner curve has a radius of curvature of more than 1 μm.

3. The deep trench isolation structure of claim 1, wherein the deep trench isolation structure is in a closed shape layout.

4. The deep trench isolation structure of claim 1, wherein the deep trench isolation structure is in a closed shape layout composed of four corners, each in the arc shape layout, and four sides.

5. The deep trench isolation structure of claim 4, wherein the distance from each of the corners to the geometric center of the deep trench isolation structure is larger than the distance from each of the side to the geometric center of the deep trench isolation structure.

6. A deep trench isolation structure, comprising:
a deep trench disposed within a substrate to surround an active area on the substrate, wherein the deep trench comprises at least a corner in a polygonal line shape layout; and
a dielectric material filled within the deep trench.

7. The deep trench isolation structure of claim 6, wherein the deep trench has a trench width of less than 4.5 μm.

8. The deep trench isolation structure of claim 6, wherein the deep trench isolation structure is in a closed shape.

9. The deep trench isolation structure of claim 6, wherein the deep trench isolation structure is in a closed shape layout composed of four corners, each in the polygonal line shape layout, and four sides.

10. The deep trench isolation structure of claim 9, wherein the distance from each of the corners to the geometric center of the deep trench isolation structure is larger than the distance from each of the side to the geometric center of the deep trench isolation structure.

11. The deep trench isolation structure of claim 6, wherein the polygonal line shape layout comprises at least two angles.

12. The deep trench isolation structure of claim 6, wherein the polygonal line shape layout has a minimal width equal to d₁ and a maximal width equal to d₂, and (d₂−d₁)/d₁ is less than (√2−1)/1.
